(19) United States
(12) Patent Application Publication
(10) Pub. No.: US 2008/0166886 A1
(43) Pub. Date: Jul. 10, 2008

(54) Substrate processing apparatus

(75) Inventors: Masanori Sakai, Takaoka-shi (JP); Norikazu Mizuno, Toyama-shi (JP); Shinya Sasaki, Toyama-shi (JP); Hirohisa Yamazaki, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., Tokyo (JP)

(21) Appl. No.: 11/902,035

(22) Filed: Sep. 18, 2007

(30) Foreign Application Priority Data
Sep. 22, 2006 (JP) 2006-257076

(51) Int. Cl. H01L 21/31; C23C 16/00

(52) U.S. Cl. 438/778; 118/725; 257/E21.24

(57) ABSTRACT

There is provided a substrate processing apparatus, comprising: a processing chamber that houses a plurality of substrates in a state of being stacked; a heating member that heats the substrate and an atmosphere in the processing chamber; a first gas supply member that supplies a source gas that thermally-decomposes; a second gas supply member that supplies oxidative gas; an exhaust member that exhausts the atmosphere in the processing chamber; and a controller that controls at least the first gas supply member, the second gas supply member, and the exhaust member. The first gas supply member further includes at least one inlet opening that introduces the source gas into the processing chamber; the first inlet opening opens so as to avoid the side of the substrate; the second gas supply member further includes at least one second inlet opening that introduces the oxidative gas into the processing chamber; the second inlet opening opens to the side of the substrate; and the controller controls the first and second gas supply members and the exhaust member, so that the source gas and the oxidative gas are alternately supplied and exhausted to the processing chamber, to form a desired film on the substrate.

### BACKGROUND

1. Technical Field

The present invention relates to a substrate processing apparatus for forming a desired thin film on a surface of a semiconductor wafer (called a wafer hereunder) and a manufacturing method of the semiconductor device and a forming method of a thin film, and particularly relates to a gas supply technique.

2. Background Art

Generally, in a vertical batch-type substrate processing apparatus, a throughput is improved by supporting a plurality of wafers in a boat and loading a boat into a substrate processing chamber. In addition, the boat is rotated around an axial center of the processing chamber, with the boat loaded into the processing chamber, and each wafer is rotated to uniformly flow a source gas on a film formation surface of the wafer, thus realizing uniformity in the in-surface film thickness for film formation.

### SUMMARY OF THE INVENTION

However, even when a substrate processing gas is uniformly flown on the surface of the wafer by rotation of the wafer, non-uniformity sometimes occurs in the in-surface film thickness of the wafer. Therefore, a technique of realizing the uniformity of the in-surface film thickness for film formation is desired, which is not apply only to the batch-type substrate processing apparatus, and an object of the present invention is to solve such a problem.

In order to achieve the aforementioned object, the present invention includes a processing chamber that houses a plurality of substrates in a state of being stacked; a heating member that heats the substrate and an atmosphere in the processing chamber; a first gas supply member that supplies a source gas which self-decomposes at a temperature of the atmosphere in the processing chamber; a second gas supply member that supplies an oxidative gas; an exhaust member that exhausts the atmosphere in the processing chamber; and a controller that controls at least the first gas supply member, the second gas supply member, and the exhaust member, the first gas supply member further including at least one first inlet opening that introduces the source gas to the processing chamber so that the first inlet opening is opened in an appearance of avoiding a direction of the substrata housed in the processing chamber, and the second gas supply member further including at least one second inlet opening that introduces the oxidative gas into the processing chamber so that the second inlet opening is opened directed in a direction of the substrate housed in the processing chamber, and the controller controlling the first gas supply member, the second gas supply member, and the exhaust member, so that the source gas and the oxidative gas are alternately supplied and exhausted to produce a desired film on the substrate.

According to the present invention, it is possible to exhibit an excellent advantage that the in-surface film thickness of the substrate can be made uniform for film formation, which is not only apply to the vertical type substrate processing apparatus.

### BRIEF DESCRIPTION OF THE DRAWINGS

FIG. 1 is a perspective view showing an outline structure of a substrate processing apparatus according to an embodiment of the present invention by a diaphanoscopy.

FIG. 2 is an explanatory view showing a substrate processing system of a substrate processing part of the substrate processing apparatus according to an embodiment of the present invention.

FIG. 3 is a sectional view taken along the line A-A of FIG. 2.

FIG. 4 is a view showing a position and a direction of a first gas supply hole and a second gas supply hole according to an embodiment of the present invention.

FIG. 5 is a view showing a comparative example.

FIG. 6 is a view showing a comparative example of a non-uniformity of an in-surface film thickness and a measurement result of the present invention.

FIG. 7 is a view showing a result of flowing N₂ gas from a first nozzle and a second nozzle respectively, and examining particles in the gas.

FIG. 8 is a view showing a state after dipping a metal Hf film into an Hf solution for 100 hours.

FIG. 9 is a view showing a sequence of a gas supply for film formation by an ALD.

### BEST MODE FOR CARRYING OUT THE INVENTION

An embodiment of the present invention will be explained hereunder, with reference to the drawings.

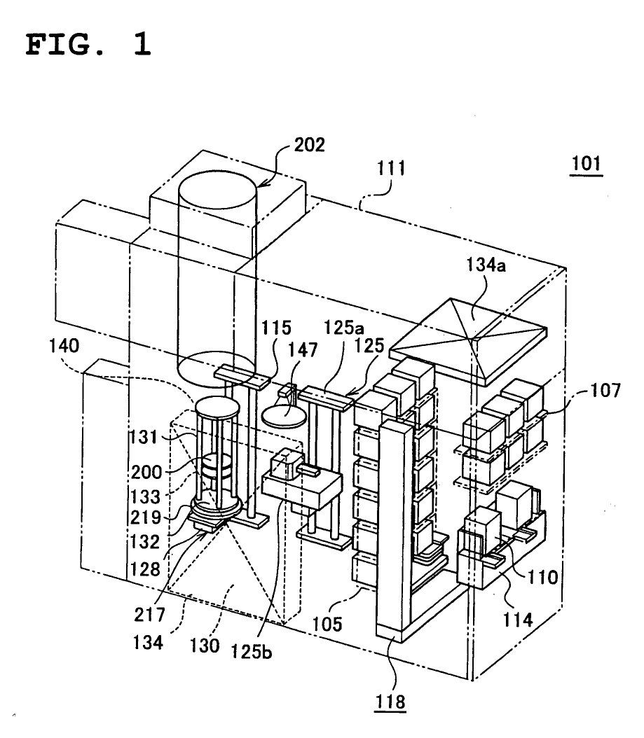

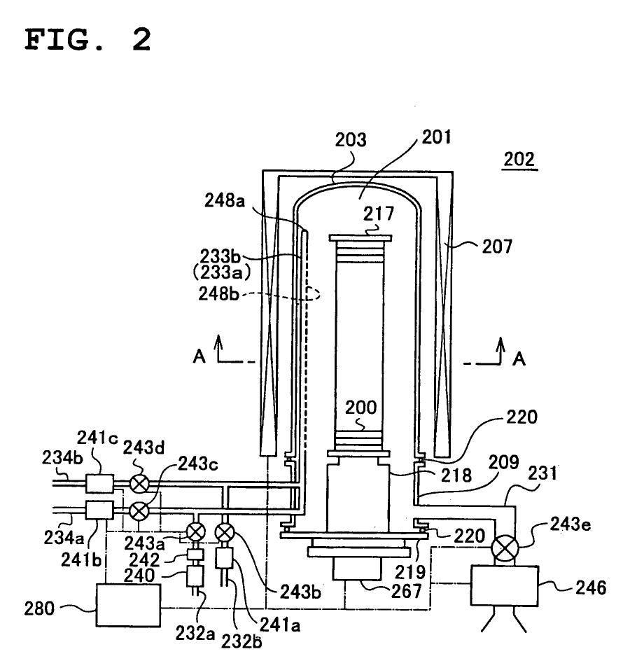

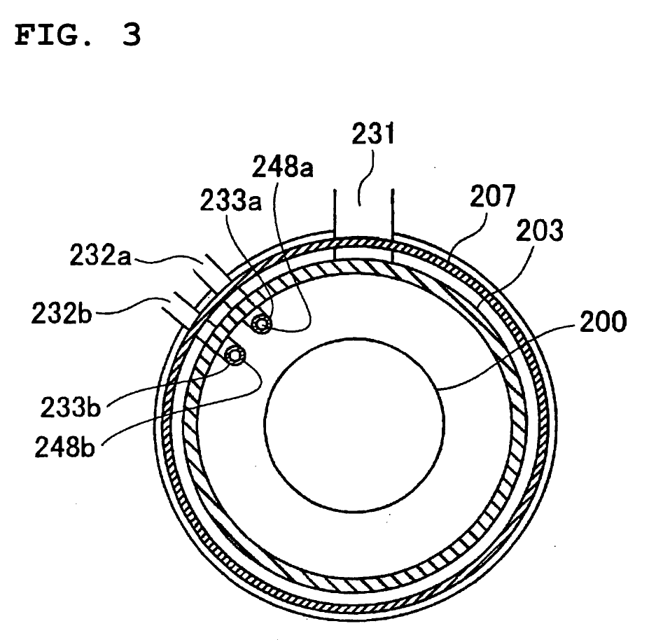

FIG. 1 is a perspective view showing an outline structure of a substrate processing apparatus according to an embodiment of the present invention by a diaphanoscopy, FIG. 2 is an explanatory view showing a substrate processing system of a substrate processing part of a processing apparatus, and FIG. 3 is a sectional view taken along the line A-A of FIG. 2.

As shown in FIG. 1, a publicly-known substrate container (called pod hereunder) 110 is used in a substrate processing apparatus 101, as a carrier that transfers a wafer 200, being a substrate. The pod 110 is transported by an in-step transport carriage that travels outside the substrate processing apparatus 101. A load port 114, being a transfer table for transferring the pod 110, is provided in a front part of a casing 111 of the substrate processing apparatus 101, and a pod storing shelf 105 for temporarily storing the pod 110, a pod opener (not shown) for opening a cap (not shown), being a lid for opening/closing a wafer charging/discharging opening of the pod 110, and a pod transport device 118 for transporting the pod 110 are provided in the front part of the casing 111, and a loading/unloading opening (not shown) for transferring the pod 110 between the in-step transport carriage and the load port 114 and a front shutter for opening/closing this charging/discharging opening are provided in a front face wall of the casing 111.

When the pod 110 is transferred from the in-step transport carriage to the load port 114, and the pod transport device 118 is moved to a pod reception position of the load port 114, the pod 110 is taken up from the load port 114 by the pod transport device 118. The pod 110 is automatically transported to a designated shelf 107 of the pod storing shelf 105, and thereafter is temporarily stored therein or is directly transported to the pod opener of a transfer chamber 130 side.

The transfer chamber 130 has a hermetically sealed structure fluidly isolated from a setting part of the pod transfer device 118 and the pod storing shelf 105, and a clean unit 134 composed of a supply fan and a dust-proof filter is provided therein so as to supply clean air, being a cleaned atmosphere or an inert gas. An oxygen concentration of the transfer chamber 130 is set at 20 ppm or less which is significantly lower than the oxygen concentration inside the casing 111 (air atmosphere).

A wafer transfer mechanism 125 is composed of a wafer transfer device (substrate transfer device) 125a and a wafer transfer device elevator (substrate transfer device elevating mechanism) 125b that elevates the wafer transfer device 125a. The wafer transfer device 125a transfers the wafer 200 between the pod 110 and a boat (substrate holding tool) 217 by a tweezer as a substrate holder.

A cap of the pod 110 is detached by a cap attachment/detachment mechanism of the pod opener, in a state that the wafer charging/discharging opening (not shown) is pressed against an opening edge portion of the wafer loading/unloading opening (not shown), to open the wafer charging/discharging opening of the pod 110. Next, the wafer transfer device 125a sequentially picks up the wafer 200 through the wafer charging/discharging opening of the pod 110 by the tweezer, so that a circumferential position, with a notch set as a reference, is matched by a notch aligning apparatus (not shown) as a substrate matching apparatus to match the circumferential position. Thereafter, the wafer 200 is charged into the boat 217 installed in a boat standby part 140 in the transfer chamber 130.

The boat 217 is supported on a seal cap 219 on a boat elevator 115 installed in the boat standby part 140 in a rear part of the casing 111, and is inserted from a lower side of a furnace orifice of a processing furnace 202 set in an upper part of the boat standby part 140. This processing furnace 202 is closed by a furnace orifice shutter 147 as a furnace orifice opening/closing mechanism, at the time other than the time of loading the boat 217.

When previously designated number of wafers 200 are charged into the boat 217, the furnace orifice of the processing furnace 202 closed by the furnace orifice shutter 147 is opened, and subsequently the boat 217 holding a wafer 200 group is loaded into the processing furnace 202 by an elevation of the boat elevator 115.

The boat 217 has a plurality of wafer holding members 131 and an elevating table 132 that supports these wafer holding members 131, so that the wafer 200 is horizontally inserted in a groove-shaped support 133 provided in multiple stages vertically spaced apart in a plurality of wafer holding members 131. When the wafer 200 is supported by each support 133, a plurality of wafers 200 are vertically arranged, with a center of the wafer aligned. In addition, each wafer 200 is horizontally held by the support 133 respectively. Note that about 50 to 125 sheets of wafers 200 are charged into the boat 217. After being loaded, the wafer 200 is subjected to an arbitrary substrate processing in the processing furnace 202. After substrate processing, in a reversed procedure to the aforementioned procedure excluding the step of matching the wafer 200 by the notch aligning apparatus, the wafer 200 and the pod 110 are discharged to outside of the casing 111.

In addition, the clean air blown out from the cleaning unit 134 is flown to the notch aligning apparatus, the wafer transfer apparatus 125a, and the boat 217 of the boat standby part 140, and thereafter is sucked by a duct 134a, which is then exhausted to the outside of the casing 111 or is circulated to a primary side (supply side), being the side of sucking the clean unit 134, and is blown out into the transfer chamber 130 again by the clean unit 134.

The processing furnace 202 will be described in detail, with reference to FIG. 2. A heater 207 as a heating member for heating the processing furnace 202 is cylindrically formed, and a reaction tube 203, being a reaction vessel, is disposed in the heater 207, to process the wafer 200, being the substrate. The reaction tube 203 is formed of a heat resistant and corrosion resistant metal such as quartz, and a manifold 209 is fitted to a lower end of the reaction tube 203 by flange connections.

The manifold 209 is opened facing a lower part, and a furnace orifice of the processing furnace 202 is extended downward. Specifically, the boat 217 is supported in a center of a boat support table 218 fitted to a tip end portion of a rotary shaft (not shown) vertically penetrating the axial center of the seal cap 219, the rotary shaft is fitted to a lower part of the seal cap 219, and the seal cap 219 is connected to a boat rotation mechanism 267 that transfers a rotation driving force as a fixing system. When the boat rotation mechanism 267 is driven, the rotary shaft is rotated and the boat 217 is rotated accordingly via the boat support table 218. Therefore, each wafer 200 is brought into contact with the atmosphere of the source gas and the oxidative gas supplied to the processing chamber 201 inside of the reaction tube 203. Thus, a uniform environment is obtained in the in-surface film thickness.

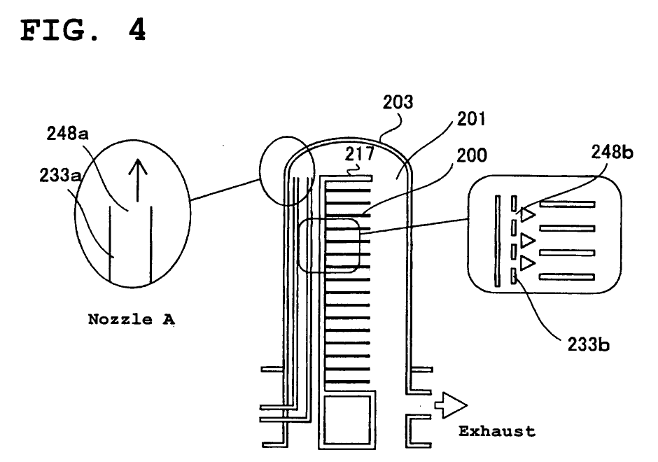

When explanation is given to a substrate processing gas supply system of the source gas and the oxidative gas, etc, with reference to FIG. 2 to FIG. 6, a plurality of species of gases are supplied to the processing chamber 201. In this example, the first gas supply tube 232a and the second gas supply tube 232b are provided as gas supply tubes. As shown in FIG. 2 to FIG. 4, a first nozzle 233a is connected to the first gas supply tube 232a, to constitute a first gas supply member, and a second nozzle 233b is connected to the second gas supply tube 232b to constitute the second gas supply member. Tip ends of the first gas supply tube 232a and the second gas supply tube 232b penetrate a side wall of the manifold 209 in a radius direction, so as to be disposed in an arcuate space between an inner wall of the reaction tube 203 that partitions the processing chamber 201 and the wafer 200. The first nozzle 233a is connected to the tip end of the first gas supply tube 232a in an L-shape, and is extended in the vicinity of the ceiling of the reaction tube 203 from the side of the furnace orifice of the reaction tube 203 along a loading direction of the wafer 200 loaded in the reaction tube 203, namely the side of the manifold 209. In addition, the second nozzle 233b is connected to the tip end of the second gas supply tube 232b in the L-shape, and is extended in the vicinity of the ceiling of the reaction tube 203 from the side of the furnace orifice of the reaction tube 203 along the loading direction of the wafer 200 of the reaction tube 203. One first gas supply hole 248a is provided as a gas inlet opening for introducing the source gas to the processing chamber 201, and a plurality of gas supply holes 248b are provided in the second nozzle 233b. In forming the film by a general CVD and ALD, being one kind of the CVD, the first gas supply hole 248a opens in a direction of avoiding the wafer 200 of the boat 217, so that the source gas (mixed gas of the raw material and the carrier gas) introduced into the processing chamber 201 from the first gas supply hole 248a is not directly introduced toward each wafer 200 of the boat 217, for making the in-surface film thickness uniform in film formation formed on the surface of each wafer 200. In this embodiment, the first gas supply hole 248a is faced to the connection part of the ceiling part of the reaction tube 203 and the side wall part of a dome-shaped reaction tube 203. Meanwhile, a plurality of second gas supply holes 248b are provided at a prescribed interval vertically so that the oxidative gas is horizontally introduced between the adjacent wafers 200. An opening area of the second gas supply hole 248a may be set same through the hole length. However, when a conduit resistance has a large influence on the film formation and the an extrusion of gas, an opening area of the second gas supply hole 248a on the side of the manifold 209 is made smaller and the opening area is sequentially made smaller toward a lower stream side, namely, toward the opening area of the ceiling side, and the substrate processing gas of the same flow rate may be introduced between each wafer 200, as an entire body of the second nozzle 233b. In addition, as shown in FIG. 3, the first nozzle 233a and the second nozzle 233b may be disposed in a close position to each other, or may be disposed at a position being symmetric across an axial line of the processing chamber 201.

Then, the first gas supply tube 232a is jointed with the first carrier gas supply tube 234a, and a first mass flow controller (fluid controller) 240, being a flow rate control device, a vaporizer 242, and a first valve 243a, being an opening/closing valve, are sequentially provided from the upper stream side to the lower stream side, a second valve 243c, being the opening/closing valve is provided on the upper stream side of the jointed point of the first gas supply tube 232a and the first carrier gas supply tube 234a, and a second mass flow controller (flow rate control device) 241b is provided on the upper stream side of the second valve 243c.

In addition, the second gas supply tube 232b is jointed with the second carrier gas supply tube 234b for supplying the carrier gas, and in the second gas supply tube 232b, a third mass flow controller 241a and a third valve 243b, being the opening/closing valve, are provided from the upper stream side to the lower stream side, and in the second carrier gas supply tube 234b, a fourth valve 243d, being the opening/closing valve, is provided on the upper stream side of the jointed point of the second gas supply tube 232b and the second carrier gas supply tube 234b, and a fourth mass flow controller 241c, being the flow rate control device (flow rate control member) is provided on the upper stream side of the fourth valve 243d.

When the raw material supplied from the first gas supply tube 232a is a liquid, for example, the source gas supplied from the first mass flow controller 240, the vaporizer 242, and the first valve 243a is jointed with the carrier gas from the first carrier gas supply tube 234, which is then transferred to the first nozzle 233a by the carrier gas, and is supplied into the processing chamber 201 from the first gas supply hole 248a. When the raw material supplied from the first gas supply tube 232a is not liquid but gas, the first mass flow controller 240 is replaced with the mass flow controller for gas from the mass flow controller for liquid. In this case, the vaporizer 242 is not necessary.

In addition, the gas supplied from the second gas supply tube 232b is jointed with the carrier gas of the second carrier gas supply tube 234b via the third mass flow controller 241a and the third valve 243b, and is transferred to the second nozzle 233b by the carrier gas, and is supplied to the processing chamber 201 from the second gas supply hole 248b.

In addition, the processing chamber 201 is connected to a vacuum pump 246 as an exhaust member via a fifth valve 243e by the gas exhaust tube 231, being the exhaust tube for exhausting the gas, and is vacuum-exhausted. Note that the fifth valve 243e is capable of vacuum-exhausting the processing chamber 201 and stop of the vacuum-exhaust of the processing chamber 201 by opening/closing the valve, and further is constituted of the opening/closing valve capable of adjusting a pressure in the processing chamber 201 by adjusting the opening degree of the valve.

The controller 280 constituting a control part is connected to the first mass flow controller 240, the second to fourth mass flow controllers 241b, 241a, 241c, the first to fifth valves 243a, 243c, 243b, 243d, 243e, the heater 207, the vacuum pump 246, the boat rotation mechanism 267, an actuator such as the boat elevator 115, and a mechanism controller, and executes a flow rate adjustment of the first mass flow controller 240 and the second to fourth mass flow controllers 241b, 241a, and 241c, an opening/closing operation of the first to fourth valves 243a, 243c, 243b, 243d, opening/closing and a pressure adjustment operation of the fifth valve 243e, temperature adjustment of the heater 207 and start/stop of the vacuum pump 246, being an exhaust member, a rotation speed adjustment of the boat rotation mechanism 267, and elevating operation control of the boat elevator 115, and controls the film formation by CVD and ALD based on a recipe.

Next, as an example of the film formation processing by using the ALD method, explanation is given to a case of forming a HfO₂ film by using TEMAH and O₃.

The ALD (Atomic Layer Deposition) method, being one of the CVD (Chemical Vapor Deposition) method is a method whereby the reactive gas, being at lest two kinds of materials used in the film formation, is supplied onto the substrate alternately one by one, and is adsorbed on the surface of the film formation of the wafer 200 in units of one atom, and performs the film formation by using a surface reaction. At this time, control of the film thickness is performed by the number of cycles of supplying the reactive gas (for example, 20 cycles are performed for forming a film of 20 Å, when the film formation speed is set at 1 Å/cycle).

For example, when the HfO₂ film is formed by the ALD method, TEMAH(Hf[NCH₃C₂H₅]₄) and tetrakis-methylethylaminohafnium), O₃ (ozone) is used as the oxidative gas, to enable a high quality film formation to be performed at a low temperature of 180 to 250° C.

### EXAMPLE 1

First, as described above, the wafer 200 is charged into the boat 217, and is loaded in the processing chamber 201. After the boat 217 is loaded into the processing chamber 201, three steps as will be described later are sequentially executed.

### (Step 1)

In step 1, TEMAH is flown to the first gas supply tube 232a as the source gas, and the carrier gas (N₂) is flown to the first carrier gas supply tube 234a. All of the first valve 243a of the first gas supply tube 232a, the second valve 243c of the first carrier gas supply tube 234a, and the fifth valve 243e of the gas exhaust tube 231 are opened. The carrier gas is flown from the first carrier gas supply tube 234a and its flow rate is adjusted by the second mass flow controller 241b. The TEMAH (Tetrakis-Ethyl Methyl Amino Hafnium: tetrakis-Nethyl-Nmethylaminohafnium) is flown from the first gas supply tube 232a and its flow rate is adjusted by the first mass flow controller 240, being a liquid mass flow controller, and thereafter is vaporized by the vaporizer 242, which is then mixed in the carrier gas whose flow rate is adjusted, and as shown in FIG. 3, the mixed gas is supplied into the processing chamber 201 from the first gas supply hole 248a of the first nozzle 233a. A surplus portion of the mixed gas of the TEMAH and the carrier gas in film formation is exhausted from the gas exhaust tube 231. At this time, the opening degree of the fifth valve 243e is appropriately adjusted, so that the inside of the processing chamber 201 is maintained in a prescribed pressure. The supply amount of the TEMAH controlled by the first mass flow controller 240 is 0.01 to 0.1 g/min, and the time required for exposing the wafer 200 to the TEMAH gas is 30 to 180 seconds. At this time, the temperature of the heater 207 is, for example, set at 250° C., with the temperature of the wafer 200 set in a range from 180 to 250° C. The TEMAH is supplied into the processing chamber 201, thereby allowing the surface reaction (chemical adsorption) to occur between the TEMAH and a surface portion such as a base film on the wafer 200.

After the source gas is supplied, the first valve 243a of the first gas supply tube 232a is closed, and the supply of the TEMAH gas is stopped, to purge the surplus portion. At this time, the fifth valve 243e of the gas exhaust tube 231 is maintained to be opened, and the inside of the processing chamber 201 is exhausted (purged) until the pressure therein becomes 20 Pa or less by the vacuum pump 246 as a reduced pressure exhaust device, and a residual TEMAH gas is exhausted from the inside of the processing chamber 201. At this time, when the inert gas such as N₂ is supplied into the processing chamber 201, efficiency in the exhaustion of the residual TEMAH gas is improved.

### (Step 3)

O₃ is flown to the second gas supply tube 232b, and the carrier gas (N₂) is flown to the second carrier gas supply tube 234b. Both of the third valve 243b of the second gas supply tube 232b and the fourth valve 243d of the second carrier gas supply tube 234b are opened. The carrier gas is flown from the second carrier gas supply tube 234b, and its flow rate is adjusted by the fourth mass flow controller 241c. O₃ is flown from the second gas supply tube 232b, and is mixed in the carrier gas whose flow rate is adjusted by the third mass flow controller 241a, and is supplied into the processing chamber 201 from the second gas supply hole 248b by the carrier gas. At this time, the processing chamber 201 is continued to be exhausted by the vacuum pump 246 as an exhaust unit, and the surplus portion is exhausted from the gas exhaust tube 231. At this time, the fifth valve 243e is appropriately adjusted, and the inside of the processing chamber 201 is maintained to a prescribed pressure. The time required for exposing the wafer 200 to O₃ is 10 to 120 seconds, and the temperature of the heater 207 is set, so that the temperature of the wafer 200 is maintained to a prescribed temperature from 180 to 250° C. in the same way as supplying the TEMAH gas of step 1. By the supply of O₃, the surface reaction occurs between the raw material of TEMAH chemically adsorbed on the surface of the wafer 200 and O₃, thus forming the HfO₂ film on the wafer 200. After the film formation, the third valve 243b of the second gas supply tube 232b and the fourth valve 243d of the second carrier gas supply tube 234b are closed, and a gas atmosphere in the processing chamber 201 is vacuum-exhausted by the vacuum pump 246. By this exhaust, the gas after contributing to the film formation of the residual O₃ is exhausted. However, at this time, when the inert gas such as N₂ is supplied into the reaction tube 203, exhaust efficiency is largely improved, in exhausting the residual gas after contributing to the film formation of O₃ from the processing chamber 201.

By setting the aforementioned steps 1 to 3 as one cycle, and repeating this cycle a plurality of times, the HfO₂ film of a desired thickness is formed on the wafer 200.

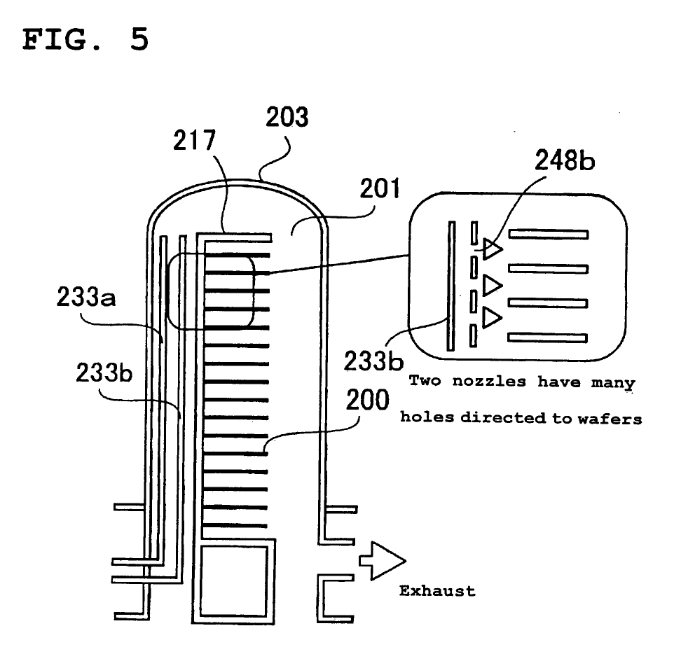

Here, a comparative example is shown in FIG. 5. FIG. 5 is a conceptual view of the comparative example of a case that a plurality of gas supply holes are provided in each of the first nozzle 233a and the second nozzle 233b.

As shown in FIG. 5, when a plurality of gas supply holes 248b are faced between the wafers 200 respectively, in-surface uniformity of the surface of the film formed on the wafer 200 is deteriorated, and the film thickness tends to be thicker on an outer peripheral side of the wafer 200 and thinner on a center side.

Therefore, a special boat called a ring boat is used for the boat 217 in which three or four wafer holding members 131 are provided. However, it is difficult to solve the non-uniformity of the in-surface film thickness even by such a boat.

However, as shown in FIG. 2 to FIG. 4, by a simple change such as not directly introducing the first gas supply hole 248a to the wafer 200 side but only avoiding the direction of the wafer 200, the in-surface film thickness of each wafer 200 is made uniform.

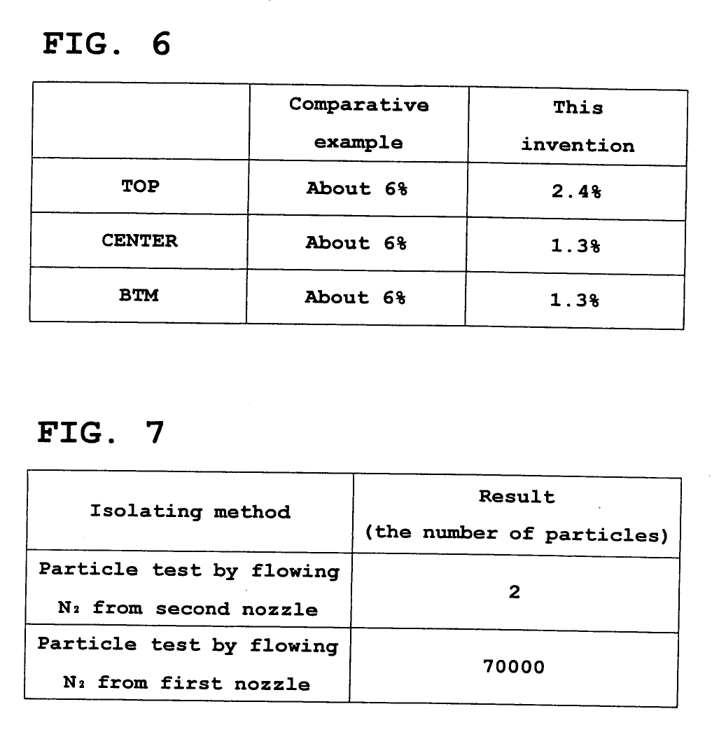

FIG. 6 shows such a result. In FIG. 6, TOP, CENTER, BTM, show an upper wafer, an intermediate wafer, and a lower wafer of the wafers 200 in a direction of a height of the boat 217 inserted into the processing chamber 201. When the film formation is performed in case of the comparative example (FIG. 5), the non-uniformity of the in-surface film thickness of the wafer 200 of the TOP, CENTER, and BTM is about 6%. However, according to the structure of this embodiment (FIG. 2 to FIG. 4), the uniformity of the in-surface film thickness is improved to 2.4%, 1.3%, and 1.3%. Accordingly, it appears that the structure of this embodiment largely contributes to the uniformity of the in-surface film thickness of a larger size of the wafer 200 hereafter.

### <Consideration>

When the mechanism of the result of FIG. 6 is considered, first, Hf (hafnium) is adsorbed on the surface of the film formation, being an adsorption surface of the wafer 200, and next, O₃, being the oxidative gas, is supplied to form the HfO₃ film. According to this process, it is the supply of the TEMAH that has a large influence on the uniformity of the film thickness in the film formation. The TEMAH is thermally decomposed at a film forming temperature of 250° C., and an intermediary body generated by the thermal decomposition has an influence. Namely, this intermediary body has a high adsorption probability, and is a factor of deteriorating the uniformity, and is assumed to be attached to the outer peripheral side of the wafer 200. When the TEMAH gas, being the source gas, is blown through the adjacent wafers 200, the film thickness becomes thicker along the gas flow. However, the film, namely, the HfO₃ film becomes thinner in other part. The same thing can be said even if the boat 217 is rotated and the wafer 200 is rotated accordingly, or they are stopped. Accordingly, it is difficult to make the in-surface film thickness uniform in the film formation, only by rotating the boat 217 as conventional.

However, as is explained in this embodiment, when the direction of supplying the source gas from the first gas supply hole 248a is set as the direction of avoiding the side of the wafer 200, the TEMAH is supplied to the wafer 200 of the boat 217 only in the form of diffusion, thus making it difficult to generate a difference in film thickness by the flow of the TEMAH gas to each wafer 200, and a result is that the uniformity in the in-surface film thickness is improved.

Meanwhile, when the oxidative gas is examined, O₃ is decomposed into O and O₂, and reaction occurs between O and TEMAH intermediary body adsorbed on the surface of the wafer 200, to form Hf—O bond. However, when there is the TEMAH intermediary body, the reaction of O occurs, and when there is no TEMAH intermediary body, no reaction of O occurs and O is exhausted from the processing chamber 201. Therefore, almost no influence is applied on the uniformity of the in-surface film thickness, and if a fixed amount or more of O is supplied to the wafer 200, an entire surface for film formation of the wafer 200 is covered by O. Therefore, as shown in FIGS. 2 to 4, there is no case of generating an influence on the in-surface uniformity of the film thickness by a gas flow supplied from the gas supply hole. Also, from the side of a gas extrusion, when the film is formed by ALD, an event of purging the gas atmosphere in the processing chamber 201 by exhaustion is required, so that the TEMAH gas and O₃, being the oxidative gas, are not mixed to cause reaction in a gas layer. In the extrusion of the gas atmosphere at this time, it is preferable to provide a plurality of second gas supply holes 248b and these second gas supply holes 248b are faced between wafers 200 respectively.

Note that according to this embodiment, the number of the first gas supply hole 248a is set as one, and this gas supply hole 248a is set, so that the source gas is introduced in a direction of avoiding the direction of the wafer 200 side. However, a plurality of first gas supply holes 248a may be set, and by turning these first gas supply holes 248a in a direction other than the direction of the wafer 200, the raw materials in the TEMAH gas may be dispersed and adsorbed on the upper surface of each wafer 200, namely, on the film formation surface. In such a structure also, the source gas is adsorbed by dispersion and the in-surface film thickness of each wafer is made uniform.

### EXAMPLE 2

Incidentally, when the HfO film is formed in the wafer 200 composed of silicon, by ALD using the substrate processing apparatus, the cycle of the following (1) to (7) is repeated to form the HfO film of a prescribed thickness, such as (1) the boat 217 is transferred to the wafer 200→(2) the boat 217 is inserted into the processing chamber 201 in which an atmosphere temperature is increased to 250° C.→(3) the atmosphere in the processing chamber 201 is exhausted (evacuated) by the vacuum pump 246 as an exhaust member→(4) mixed gas of the TEMAH gas and the carrier gas as the source gas is supplied from the first gas supply hole 248a (three minutes)→(5) the atmosphere in the processing chamber is exhausted by N₂ purge (twenty seconds)→(6) O₃ gas, being the oxidative gas, is supplied from the second gas supply hole 248b, to form the HfO film by a thermochemical reaction of Hf and adsorbed on the surface of the wafer 200→(7) the boat 217 is taken out from the processing chamber 201.

The TEMAH and O₃ are alternately flown on the wafer 200, thereby forming the HfO₂ film. However, the TEMAH, being the raw material of the ALD film formation, is decomposed from 120° C., and therefore not the HfO₂ film but the metal Hf film is formed on an inner surface of the first nozzle 233a. Thus, during a repeated cycle of (1) to (7), generally particles are generated in a stage of a thin accumulated film thickness of HfO₂ of the processing chamber 201 such as about 0.5 μm, with respect to 1 μm which is an index of the accumulated film thickness at the time of a regular maintenance.

Therefore, after processing the substrate, N₂ gas is flown from the first nozzle 233a and the second nozzle 233b, respectively, and the particles in the gas are checked. Then, as shown in FIG. 7, it was found that the number of the particles of the first nozzle 233a for supplying the TEMAH gas to the processing chamber 201 was 70000, and the number of the particles of the second nozzle 233b for supplying the oxidative gas was 2. Accordingly, the particles are caused by an attachment of the first nozzle 233a and scattered to the processing chamber 201 from the first nozzle 233a. In addition, a result of XPS (X-Ray Energy Diversive X-Ray Spectrometer) shows that the film formed on the wafer 200, namely, the component of HfO₂ satisfies Hf:O₂=1:2, while component composition of the particles satisfies Hf:O₂=30:1, wherein the component of O₂ is extremely low. From this point also, it can be easily estimated that the particles are not brought into contact with O₃. Thus, the particles are rich in Hf, and a scattered matter scattered from the first nozzle 233a for supplying the TEMAH gas is a factor of contaminating the wafer 200, and the contamination of the wafer 200 needs to be prevented by a regular self-cleaning in ALD and HfO. In addition, scattering of the particles from the first nozzle 233a is caused by a thermal stress and a film stress which are added during film formation, thus peeling off the film of the inner surface of the first nozzle 233a and the particles are thereby produced. Namely, the film adhered to the inner surface of the first nozzle 233a has few chance of being peeled off as it is. However, when a heat produced by up/down of the temperature acts thereon, a crack due to a thermal stress occurs to the film by a difference of thermal expansion of the film and the quartz by repeated contraction/expansion, ultimately resulting in the peel-off of the film from the inner surface of the first nozzle.

Therefore, in order to remove the metal Hf film, being a deposit, use of a WET cleaning or Institu Cleaning (etching) is considered.

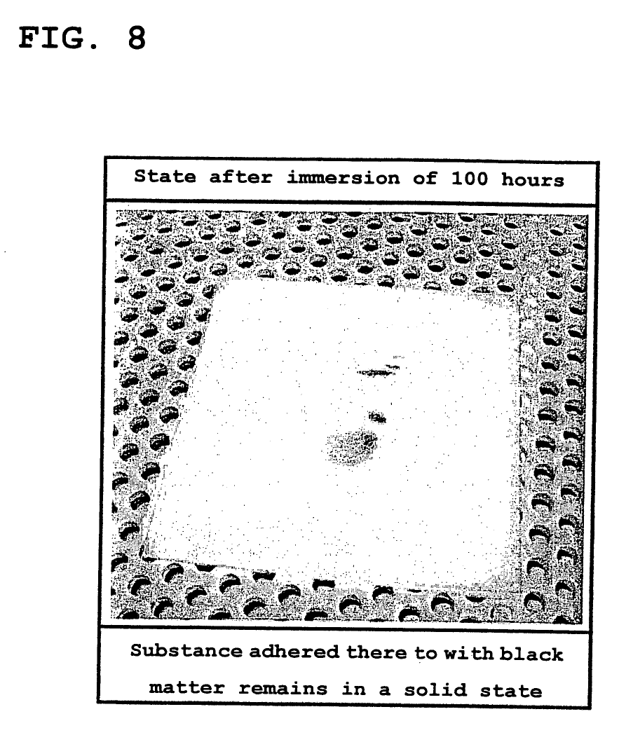

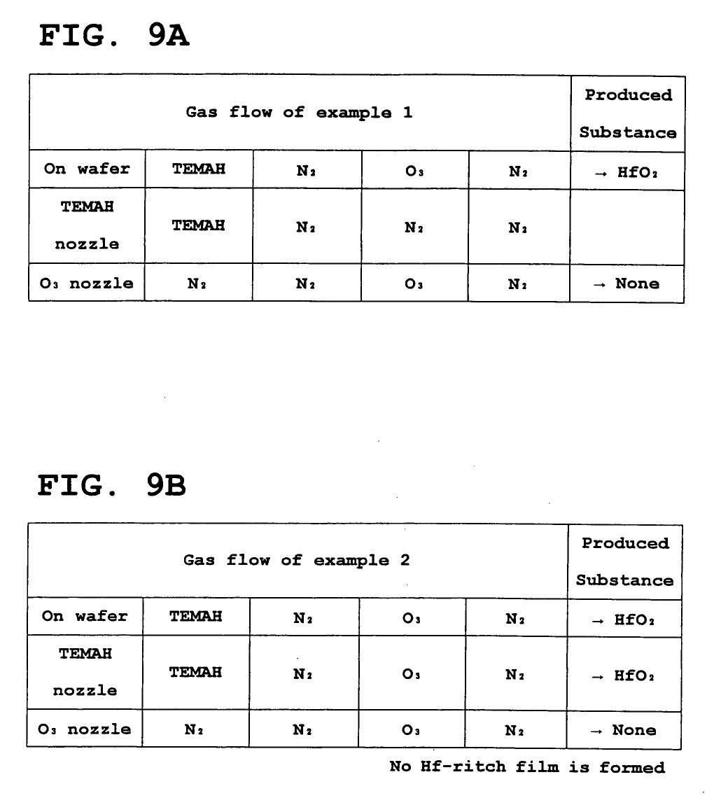

In a case of the WET cleaning, mixed solution of HF (Hydro Fluoric) and DIW (De Ionaized Water:pure) is used for the cleaning liquid. Before executing the Insitu Cleaning as a factor of experiment, HfO₂ and a stuck material inside of the first nozzle 233a are infiltrated in the HF solution and an etching condition was examined. The HfO₂ film was visually confirmed to be etched in the HF solution (25% of HF solution). An etching rate was 1000 A/min. However, as shown in FIG. 8, the metal Hf film (also called an Hf rich film), being an adhered matter inside of the first nozzle 233a, exists in a black solid sate even if being infiltrated in the HF solution (25% of the HF solution) for 100 hours, thus involving the problem that the etching rate is extremely slow compared to that of HfO₂. Generally, fluorinated acid in the HF solution in the HF solution can not be used for etching metals such as Si and Hf, but is used for etching of an oxide matter of SiO and HfO. Therefore, the metal Hf film adhered to the inner surface of the first nozzle 233a is reformed to the HfO₂ film, which is then removed by the Wet or Insitu Cleaning. As described above, slowing the etching rate is caused by a condition that the adhered matter in the first nozzle 233a is Hf rich. Therefore, in order to prevent a situation that an Hf-rich film is deposited on the first nozzle 233a, it is necessary to flow O₃ to the first nozzle 233a and intentionally oxidize the Hf-rich film. FIG. 9A shows a sequence of the gas supply by the first nozzle 233a for the film formation by the ALD according to the example 1, and FIG. 9B shows a sequence for oxidizing the Hf-rich film.

As shown in FIG. 9, in the sequence of the example 1, only N₂ for TEMAH and purging is flown inside of the TEMAH nozzle, and therefore the Hf-rich film is formed. In addition, a deposited film is not recognized as described above in the inner surface of the O₃ nozzle for supplying the oxidative gas. TEMAH and O₃ are alternately flown on the wafer 200, and the HfO₂ film is formed.

Meanwhile, in the sequence according to the example 2, TEMAH gas, being the source gas, and O₃, being the oxidative gas, are alternately flown to the TEMAH nozzle. Therefore, formation of the Hf-rich film is suppressed, and instead, the HfO₂ film is formed.

### [Additional Description]

An aspect of the present invention will be additionally described hereunder.

### [Aspect 1]

A substrate processing apparatus of the present invention includes:

a processing chamber that houses a plurality of substrates in a sate of being stacked;

a heating member that heats the substrate and an atmosphere in the processing chamber;

a first gas supply member that supplies a source gas that self decomposes at an atmosphere temperature in the processing chamber heated by the heating member;

a second gas supply member that supplies an oxidative gas;

an exhaust member that exhausts the atmosphere in the processing chamber; and

a controller that controls at least the first gas supply member, the second gas supply member, and the exhaust member,

the first gas supply member further including at least one first inlet opening for introducing the source gas into the processing chamber;

the first inlet opening being opened so as to avoid a direction of the side of the substrate housed in the processing chamber;

the second gas supply member further including at least one second inlet opening for introducing the oxidative gas into the processing chamber;

the second inlet opening being opened directed toward the side of the substrate housed in the processing chamber; and

the controller controlling the first gas supply member, the second gas supply member, and the exhaust member, so that the source gas and the oxidative gas are alternately supplied and exhausted so as to form a desired film on the substrate.

Here, the “stack” specifies an arrangement state of the wafers arranged, with a prescribed space sandwiched between the adjacent substrates, and the “prescribed space” means an interval allowing the source gas after thermal decomposition to be diffused. In addition, “the source gas and the oxidative gas are alternately supplied and exhausted to the processing chamber to form a desired film on the substrate” and this means the formation of the film on the substrate by alternately repeating the step of exhausting the source gas from the processing chamber after supplying the source gas into the processing chamber, and the step of exhausting the source gas from the processing chamber after the oxidative gas is supplied to the processing chamber.

Note that explanation has given to a case that the embodiment of the present invention is applied to a batch-type vertical substrate processing apparatus. However, the present invention is not limited thereto and also can be applied to a horizontal sheet-fed substrate processing apparatus.

What is claimed is:

1. A substrate processing apparatus, comprising:
a processing chamber that houses a plurality of substrates in a state of being stacked;
a heating member that heats said substrate and an atmosphere in said processing chamber;
a first gas supply member that supplies a source gas that self-decomposes at an atmosphere temperature in said processing chamber heated by said heating member;
a second gas supply member that supplies oxidative gas;
an exhaust member that exhausts the atmosphere in said processing chamber; and
a controller that controls at least said first gas supply member, said second gas supply member, and said exhaust member,
said first gas supply member further comprising at least one inlet opening that introduces said source gas into said processing chamber;
said first inlet opening being opened so as to avoid a direction of the side of said substrate housed in said processing chamber;
said second gas supply member further comprising at least one second inlet opening that introduces said oxidative gas into said processing chamber;
said second inlet opening being opened directed toward the side of the substrate housed in said processing chamber;
said first gas supply member further having a first nozzle extending along a stack direction of said substrate, with said first inlet opening provided on a tip end of said first nozzle;
said second gas supply member further having a second nozzle extending along the stack direction of said substrate, with a plurality of said second inlet openings provided on a side wall of said second nozzle;
said heating member heating said substrate and the atmosphere of an inside of said processing chamber to 180 to 250° C.; and
said controller controlling said first gas supply member, said second gas supply member, and said exhaust member, to alternately supply and exhaust tetrakis-methyl-ethyl-amino-hafnium, being said source gas, and ozone, being said oxidative gas, to said processing chamber, so as to form an oxide hafnium film on said substrate.

2. A substrate processing apparatus, comprising:
a processing chamber that houses a plurality of substrates in a state of being stacked;
a heating member that heats said substrate and an atmosphere of an inside of said processing chamber;
a first gas supply member that supplies a source gas that self-decomposes at an atmosphere temperature inside of said processing chamber heated by said heating member;
a second gas supply member that supplies oxidative gas;
an exhaust member that exhausts the atmosphere inside of said processing chamber; and
a controller that controls at least said first gas supply member, said second gas supply member, and said exhaust member,
said first gas supply member further comprising at least one inlet opening that introduces said source gas into said processing chamber;
said first inlet opening being opened so as to avoid a direction of the side of said substrate housed in said processing chamber;
said second gas supply member further comprising at least one second inlet opening that introduces said oxidative gas into said processing chamber;
said second inlet opening being opened directed toward the side of the substrate housed in said processing chamber; and
said controller controlling said first gas supply member, said second gas supply member, and said exhaust member, to alternately supply and exhaust said source gas and said oxidative gas to said processing chamber, so as to form a desired film on said substrate.

3. The substrate processing apparatus according to claim 2, wherein
said first gas supply member further has a first nozzle extending along a stack direction of said substrate, with one said inlet opening provided on a tip end of said first nozzle;
said second gas supply member further has a second nozzle extending along the stack direction of said substrate; and
a plurality of said second inlet openings are provided on a side wall of said second nozzle.

4. The substrate processing apparatus according to claim 3, wherein each of said second inlet openings is provided in said second nozzle at a prescribed interval in said stack direction.

5. The substrate processing apparatus according to claim 2, wherein said source gas is introduced into said processing chamber in a vertical direction toward a ceiling part of said processing chamber from said first inlet opening; and said oxidative gas is introduced into said processing chamber in a horizontal direction from each of said second inlet openings.

6. The substrate processing apparatus according to claim 2, wherein said heating member heats said substrate and the atmosphere in said processing chamber to 180 to 250° C., and said source gas is selected to be tetrakis-methylethylaminohafnium and said oxidative gas is selected to be ozone, to form an oxide hafnium film on said substrate as said film.

7. The substrate processing apparatus according to claim 2, wherein said source gas is supplied to said substrate by mainly diffusion, and said oxidative gas is supplied to said substrate mainly by gas flow.

8. The substrate processing apparatus according to claim 2, wherein an inert gas is supplied from said second gas supply member when said source gas is supplied to said processing chamber from said first gas supply member; and when said oxidative gas is supplied to said processing chamber from said second supply member, an oxidative gas is supplied from said first gas supply member.

9. A forming method of a thin film, comprising:
housing a plurality of substrates into a processing chamber in a state of being stacked;
heating said substrate and an atmosphere of an inside of said processing chamber by using a heating member;
supplying a source gas that self-decomposes at an atmosphere temperature inside of said processing chamber heated by said heating member by a first gas supply member so as to avoid a direction of the side of said substrate housed in said processing chamber;
supplying an oxidative gas to said processing chamber by a second gas supply member; and
exhausting the atmosphere inside of said processing chamber by an exhaust member,
said source gas and said oxidative gas being alternately supplied and exhausted to said processing chamber, to form a desired film on said substrate.

10. The forming method of a thin film according to claim 9, wherein
when said source gas is supplied to said processing chamber from said first gas supply member, an inert gas is supplied from said second gas supply member; and
when said oxidative gas is supplied to said processing chamber from said second supply member, an oxidative gas is supplied from said first gas supply member.
